(19) United States
(12) Patent Application Publication
(10) Pub. No.: US 2021/0356515 A1
(43) Pub. Date: Nov. 18, 2021

(54) DISPLAY PANEL

(71) Applicant: TCL CHINA STAR OPTOELECTRONICS TECHNOLOGY CO., LTD., Shenzhen, Guangdong (CN)

(72) Inventors: Zhixiong JIANG, Shenzhen (CN); Yanhong MENG, Shenzhen (CN)

(21) Appl. No.: 16/618,928

(22) PCT Filed: May 10, 2019
(86) PCT No.: PCT/CN2019/086308

§ 371 Date: Dec. 3, 2019

(30) Foreign Application Priority Data
Apr. 11, 2019 (CN) 201910290538.3

(51) Int. Cl. G01R 31/28; H01L 27/12

(52) U.S. Cl. CPC G01R 31/2884; G02F 1/136286; H01L 27/124

(57) ABSTRACT

A display panel is provided. A first metal layer is patterned to form a first electrode and a second metal layer is patterned to form a second electrode. A projection of the second electrode and a projection of the first electrode are overlapped on a substrate. A gate insulating layer is disposed between the first metal layer and the second metal layer. A test circuit layer is electrically connected to the second electrode. An electrostatic test electrode includes a first test electrode and a second test electrode. The first test electrode is electrically connected to the first electrode and the second test electrode is electrically connected to the test circuit layer. The gate insulating layer disposed in an intermediate region has an antistatic ability.

### BACKGROUND OF INVENTION

### Field of Invention

The present invention relates to a field of display technology, and more particularly, to a display panel.

### Description of Prior Art

Currently, display panels are generally required to test a gate insulating layer against electrostatic breakdown during manufacturing. As shown in FIG. 1, The display panels include a substrate 100, a first metal layer 110, a gate insulating layer 120, a second metal layer 130, and two electrodes (not shown) of an electrostatic test electrode electrically connected to the first metal layer 110 and the gate insulating layer 120, respectively. A thickness of the gate insulating layer 120 disposed in a slope region 111 is generally less than a thickness of the gate insulating layer 120 disposed in an intermediate region during depositing the gate insulating layer 120. It is easy to generate static electricity in the slope region 111. When researchers start to measure the static electricity, the slope region 111 is often broken down by the static electricity, so the electrostatic breakdown resistance of the gate insulating layer 120 disposed in the intermediate region with a general thickness cannot be characterized.

Therefore, the display panels have a technical problem that the electrostatic breakdown resistance of the gate insulating layer is measured inaccurately and needs to be improved.

### SUMMARY OF INVENTION

A display panel is provided to solve a technical problem that electrostatic breakdown resistance of the gate insulating layer is measured inaccurately.

To solve the above problems, technical solutions are described as follows:

In one embodiment, a display panel includes:
a substrate;
a first metal layer, and the first metal layer is patterned to form a first electrode;
a second metal layer, and the second metal layer is patterned to form a second electrode, and a projection of the second electrode and a projection of the first electrode are overlapped on the substrate;
a gate insulating layer disposed between the first metal layer and the second metal layer;
an insulating layer;
a test circuit layer electrically connected to the second electrode, and a connection region is disposed in a projection area of the second electrode on the substrate; and
an electrostatic test electrode, and the electrostatic test electrode includes a first test electrode and a second test electrode, the first test electrode is electrically connected to the first electrode, and the second test electrode is electrically connected to the test circuit layer.

In one embodiment, the first metal layer is formed on the substrate, and the gate insulating layer is formed on a side of the first metal layer away from the substrate, and the second metal layer is formed on a side of the gate insulating layer away from the first metal layer, and the insulating layer is formed on a side of the second metal layer away from the gate insulating layer, and the test circuit layer is formed on a side of the insulating layer away from the second metal layer.

In one embodiment, the display panel includes a low temperature polycrystalline silicon thin film transistor, and the first metal layer is further patterned to form a gate of the low temperature polycrystalline silicon thin film transistor.

In one embodiment, the display panel includes an oxide thin film transistor, and the second metal layer is further patterned to form a gate of the oxide thin film transistor.

In one embodiment, the display panel includes a storage capacitor, and the first metal layer is patterned to form a first metal plate of the storage capacitor, and the second metal layer is patterned to form a second metal plate of the storage capacitor.

In one embodiment, the insulating layer is a passivation layer.

In one embodiment, the insulating layer is a stacking structure including a passivation layer and an interlayer insulating layer.

In one embodiment, the display panel is a liquid crystal display panel, and the test circuit layer is a pixel electrode of the liquid crystal display panel.

In one embodiment, the display panel is an organic light emitting diode (OLED) display panel, and the test circuit layer is a common electrode of the OLED display panel.

In one embodiment, the test circuit layer is formed on the substrate, and the second metal layer is formed on a side of the test circuit layer away from the substrate, and the gate insulating layer is formed on a side of the second metal layer away from the test circuit layer, and the first metal layer is formed on a side of the gate insulating layer away from the second metal layer, and the insulating layer is formed on a side of the first metal layer away from the gate insulating layer.

In one embodiment, the display panel includes a low temperature polycrystalline silicon thin film transistor, and the second metal layer is further patterned to form a gate of the low temperature polycrystalline silicon thin film transistor.

In one embodiment, the display panel includes an oxide thin film transistor, and the first metal layer is further patterned to form a gate of the oxide thin film transistor.

In one embodiment, the display panel includes a storage capacitor, and the first metal layer is patterned to form a first metal plate of the storage capacitor, and the second metal layer is patterned to form a second metal plate of the storage capacitor.

In one embodiment, the insulating layer is a passivation layer.

In one embodiment, the insulating layer is an interlayer insulating layer.

In one embodiment, the insulating layer is a stacking structure including a passivation layer and an interlayer insulating layer.

In one embodiment, a first via hole is defined in the first electrode, and a second via hole is defined in the test circuit layer, and the first test electrode is electrically connected to the first electrode through the first via hole, and the second test electrode is electrically connected to the test circuit layer through the second via hole.

In one embodiment, a first connection terminal is formed in the first electrode, and a second connection terminal is formed in the test circuit layer, and the first test electrode is electrically connected to the first electrode through the first connection terminal, and the second test electrode is electrically connected to the test circuit layer through the second connection terminal.

In one embodiment, a third connection terminal is formed in the first test electrode, and a fourth connection terminal is formed in the second test electrode, and the first test electrode is electrically connected to the first electrode through the third connection terminal, and the second test electrode is electrically connected to the test circuit layer through the fourth connection terminal.

In one embodiment, a first connection terminal is formed in the first electrode, and a second connection terminal is formed in the test circuit layer, and a third connection terminal is formed in the first test electrode, and a fourth connection terminal is formed in the second test electrode, and the first connection terminal is electrically connected to the third connection terminal, and the second connection terminal is electrically connected to the fourth connection terminal.

A display panel includes a substrate, a first metal layer, a second metal layer, a gate insulating layer, an insulating layer, a test circuit layer, and an electrostatic test electrode. The first metal layer is patterned to form a first electrode. The second metal layer is patterned to form a second electrode. A projection of the second electrode and a projection of the first electrode are overlapped on the substrate. The gate insulating layer is disposed between the first metal layer and the second metal layers. The test circuit layer is electrically connected to the second electrode, and a connection region is disposed in a projection area of the second electrode on the substrate. The electrostatic test electrode includes a first test electrode and a second test electrode, the first test electrode is electrically connected to the first electrode, and the second test electrode is electrically connected to the test circuit layer. In one embodiment, the first test electrode is electrically connected to the first electrode and the second test electrode is electrically connected to the test circuit layer, and a gate insulating layer is further disposed between the first metal layer and the test circuit layer, so a slope region of the gate insulating layer is thicker and it hard to generate static electricity. Therefore, the electrostatic test electrode can measure an antistatic ability of the gate insulating layer disposed in an intermediate region.

### BRIEF DESCRIPTION OF DRAWINGS

In order to clearly illustrate the technical solutions, the drawings used in the description of the embodiments will be briefly described below. It is obvious that the drawings in the following description are only some embodiments of the present invention. Other drawings can also be obtained from those skilled in the art based on the drawings without paying any creative effort.

FIG. 1 is a schematic structural view of a conventional display panel.

FIG. 2 is a first schematic structural view of a display panel according to one embodiment of the present invention.

FIG. 3 is a second schematic structural view of a display panel according to one embodiment of the present invention.

FIG. 4 is a third schematic structural view of a display panel according to one embodiment of the present invention.

FIG. 5 is a fourth schematic structural view of a display panel according to one embodiment of the present invention.

### DETAILED DESCRIPTION OF PREFERRED EMBODIMENTS

The following description of the embodiments is provided by reference to the following drawings. Directional terms mentioned in this application, such as “up,” “down,” “forward,” “backward,” “left,” “right,” “inside,” “outside,” “side,” etc., are merely indicated the direction of the drawings. Therefore, the directional terms are used for illustrating and understanding of the application rather than limiting thereof. In the figures, elements with similar structure are indicated by the same reference numerals.

A display panel is provided to solve a technical problem that electrostatic breakdown resistance of a gate insulating layer is measured inaccurately.

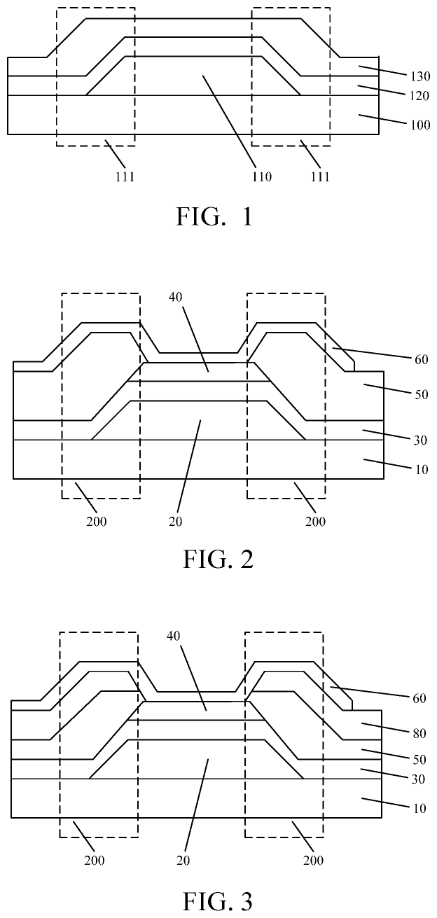

Referring to FIG. 2, which is a first schematic structural view of a display panel according to one embodiment of the present invention. The display panel includes a substrate 10, a first metal layer, a gate insulating layer 30, a second metal layer, an insulating layer 50, a test circuit layer 60, and an electrostatic test electrode.

The substrate 10 may be a flexible substrate, and material of the flexible substrate may include at least one of polyimide, polyethylene terephthalate, polyethylene naphthalate, polycarbonate, polyarylate, polyether sulfone, and a combination thereof The substrate 10 may also be a rigid substrate, specifically a glass substrate or other rigid substrate. The embodiment does not limit the material of the substrate.

The first metal layer is formed on the substrate 10 and is patterned to form a first electrode 20, and material of the first metal layer may include at least one of titanium, aluminum, copper, and a combination thereof. The embodiment does not limit the material of the first metal layer, and the material is merely needed to transmit a test signal without limiting.

The gate insulating layer 30 is formed on a side of the first metal layer away from the substrate 10, and material of the gate insulating layer 30 generally includes silicon oxide (SiOx), silicon nitride (SiNx), silicon oxynitride (SiON), or be a sandwich structure made of silicon oxide (SiOx), silicon nitride (SiNx), silicon oxynitride (SiON).

In one embodiment, the gate insulating layer 30 is formed on the first metal layer by a chemical vapor deposition method.

The second metal layer is formed on a side of the gate insulating layer 30 away from the first metal layer 20, and the second metal layer is patterned to form a second electrode 40. The second metal layer are made of an aluminum layer, a titanium layer, a copper layer or other metal material. A projection of the second electrode 40 and a projection of the first electrode 20 are overlapped on the substrate 10. In the embodiment, a projection range of the second electrode 40 on the substrate 10 is equal to the projection of the first electrode 20 on the substrate 10, and the overlapping region corresponds to the gate insulating layer 30 disposed in the intermediate region which has a general thickness.

Because the projection range of the second electrode 40 on the substrate 10 is equal to the projection of the first electrode 20 on the substrate 10, the second electrode 40 does not cover the gate insulating layer 30 disposed in the slope region 200. Thus, when there is a current on both the first electrode 20 and the second electrode 40, the gate insulating layer 30 disposed in the slope region 200 does not have a current accumulation, that is, current only acts on the gate insulating layer 30 disposed in the intermediate region, and electrostatic breakdown resistance characteristics of the gate insulating layer 30 can be measured more accurately.

In one embodiment, the display panel includes a low temperature polycrystalline silicon thin film transistor, and the first metal layer is further patterned to form a gate of the low temperature polycrystalline silicon thin film transistor.

Low temperature polycrystalline silicon thin film transistors have advantages of low temperature manufacturing of the thin film transistors, high carrier mobility, and small device sizes, and are widely used in display panels. In one embodiment, the low temperature polycrystalline silicon thin film transistor is a bottom gate structure, and the first metal layer is patterned to form a gate of the low temperature polycrystalline silicon thin film. The gate of the low temperature polycrystalline silicon thin film and the first electrode 20 are disposed on the same layer.

In one embodiment, the display panel includes an oxide thin film transistor, and the second metal layer is further patterned to form a gate of the oxide thin film transistor.

Oxide thin film transistors have a simple manufacturing process, few lithography process, and good uniformity, and are widely used for high-generation and large-sized display panels. In the embodiment, the oxide thin film transistor is a top gate structure, and the second metal layer is patterned to form a gate of the oxide thin film transistor. The gate of the oxide thin film transistor and the second electrode 40 are disposed on the same layer.

In one embodiment, the display panel includes a storage capacitor, and the first metal layer is a first metal plate of the storage capacitor and the second metal layer is a second metal plate of the storage capacitor. An insulating layer 50 is formed on a side of the second metal layer away from the gate insulating layer 30.

In one embodiment, the insulating layer 50 is a passivation layer, and material of the insulating layer 50 includes silicon oxide (SiOx), silicon nitride (SiNx), or be a sandwich structure made of silicon oxide (SiOx) and silicon nitride (SiNx), which is used to protect the second electrode 40, so the second electrode 40 is prevented by keeping water vapor or oxygen away. Therefore, corrosion or oxidation can be prevented.

In one embodiment, the insulating layer 50 is a stacking structure including a passivation layer and an interlayer insulating layer. The interlayer insulating layer is formed on a side of the second metal layer away from the gate insulating layer 30. The passivation layer is formed on a side of the interlayer insulating layer away from the second metal layer. Material of the interlayer insulating layer is organic photoresist, and material of the passivation layer includes silicon oxide (SiOx), silicon nitride (SiNx), or be a sandwich structure made of silicon oxide (SiOx) and silicon nitride (SiNx).

The test circuit layer 60 is formed on the insulating layer 50 away from the second layer. The test circuit layer 60 is electrically connected to the second electrode 40, and a connection region is disposed in a projection area of the second electrode 40 on the substrate 10.

The connection region electrically connecting the test circuit layer 60 to the second electrode 40 is disposed in a projection area of the second electrode 40 on the substrate 10, that is, the connection region is merely disposed at an intermediate region of the gate insulating layer 30, in which the intermediate region has a general thickness. When there is a current on the test circuit layer 60 and the first electrode 20, the gate insulating layer 30 disposed in the slope region 200 does not have a current accumulation, that is, current only acts on the gate insulating layer 30 disposed in the intermediate region, and electrostatic breakdown resistance characteristics of the gate insulating layer 30 can be measured more accurately.

At least one via hole (not shown) is formed on the insulating layer 50, and the least one via hole completely passes through the insulating layer 50, so the second electrode 40 is exposed by the at least one via hole and the test circuit layer 60 is electrically connected to the second electrode 40 by the at least one via hole. Thus, the second electrode 40 electrically connected to the test circuit layer 60 is ensured to be excellent connected during measuring, and a signal of the second electrode 40 is ensured to be well transmitted to the test circuit layer 60.

In one embodiment, the at least one via hole is formed by etching the insulating layer 50, specifically the etching may be dry etching or wet etching. Of course, the at least one via hole can also be formed by other methods. The embodiment does not limit method of forming the at least one via hole.

In one embodiment, a display panel is a liquid crystal display panel, and the test circuit layer 60 is a pixel electrode of the liquid crystal display panel. In one embodiment, a display panel is an organic light emitting diode (OLED) display panel, and the test circuit layer 60 is a common electrode of the OLED display panel. The common electrode is a transparent conductive layer made of indium tin oxide (ITO).

The electrostatic test electrode is used for testing an antistatic ability of the gate insulating layer 40. The electrostatic test electrode includes a first test electrode (not shown) and a second test electrode (not shown). The first test electrode is electrically connected to the first electrode 20, and the second test electrode is electrically connected to the test circuit layer 60.

In the conventional display panel, the first test electrode of the electrostatic test electrode is electrically connected to the first metal layer, and the second test electrode is electrically connected to the second metal layer. When testing an electrostatic breakdown characteristic of the gate insulating layer by the electrostatic test electrode, it is necessary to energize the first electrode and the second electrode and gradually increase the current.

The gate insulating layer is disposed between the first metal layer and the second metal layer. The gate insulating layer is normally non-conductive, and thus when the current supplied by the electrostatic test electrode is low, the gate insulating layer is not broken down. The first metal layer and the second metal layer are not electrically conductive, that is, the first electrode and the second electrode of the electrostatic test electrode are not electrically conductive, and thus no current is detected. When the current supplied by the electrostatic test electrode gradually increases to reach a threshold value, the gate insulating layer is broken down. The first metal layer and the second metal layer are electrically conductive at a breakdown spot, and the first electrode and second electrode of the electrostatic test electrode are electrically conductive, and thus a current is detected. In the electrostatic test electrode, the first electrode is electrically connected to the first metal layer and the second electrode is electrically connected to the second metal layer, and then increasing the current to measure the electrostatic breakdown resistance of the gate insulating layer. By detecting the current or not, the gate insulating layer is achieved to have electrostatic breakdown resistance, and the current value reflects the antistatic ability of the gate insulating layer when the first electrode and the second electrode are electrically conductive.

However, when the gate insulating layer is formed, a slope region is also formed. A thickness of the gate insulating layer disposed at an edge of the slope region is small, and a thickness of the gate insulating layer disposed in an intermediate region is large. Generally, the gate insulating layer disposed in the intermediate region being electrostatic breakdown or not is measured by the electrostatic test electrode. Because a thickness of an edge of the slope region of the gate insulating layer is small, the edge of the slope region of the gate insulating layer is often first broken down when an electrostatic test electrode applies a current. At the same time, the first electrode and the second electrode are electrically conductive, and the electrostatic test electrode receives an electrostatic value. However, the electrostatic value reflects the antistatic ability of the gate insulating layer disposed at the edge of the slope region of and does not reflect the antistatic ability of the gate insulating layer disposed in the intermediate region. Thus, the result measured by the electrostatic test electrode is inaccurate, and the value is smaller than an actual value, and it is difficult to characterize the electrostatic breakdown resistance of the gate insulating layer disposed in the intermediate region which has a general thickness.

In one embodiment, a signal is transmitted from the second electrode 40 to the test circuit layer 60. When the electrostatic test electrode is operated, the first test electrode is electrically connected to the first electrode 20 and the second test electrode is electrically connected to the test circuit layer 60. The insulating layer 50 is further formed on the gate insulating layer 30 and is also disposed between the test circuit layer 60 and the first electrode 20. A thickness of the insulating layer 50 disposed in the slope region 200 is increased, and the thickness of the insulating layer 50 disposed in the slope region 200 is not less than a thickness of the gate insulating layer 30 disposed in the intermediate region. Meanwhile, projections of the second electrode 40 and the first electrode 20 are overlapped on the substrate 10, and the test circuit layer 60 is electrically connected to the second electrode 40, and the connection region is disposed in the projection area of the second electrode 40 on the substrate 10. Thus, when current is applied to the electrostatic test electrode, the gate insulating layer 30 disposed in the slope region 200 does not have current accumulation, that is, the current only acts on the gate insulating layer 30 disposed in the intermediate region.

Therefore, when a test current applied to the electrostatic test electrode is gradually increased, the gate insulating layer 30 disposed in the slope region 200 is not first broken down. In contrast, the gate insulating layer 30 disposed in the intermediate region is first broken down, so that a current value measured by the electrostatic test electrode when the first test electrode and the second test electrode are electrically conductive, and the measured current value correctly reflects the electrostatic breakdown resistance of the gate insulating layer disposed in the intermediate region which has a general thickness.

There are several methods to make the electrostatic test electrode to connect to the display panel. In one embodiment, the first electrode 20 is formed with a first via hole (not shown), and the test circuit layer 60 is formed with a second via hole (not shown). The first test electrode is electrically connected to the first electrode 20 through the first via hole, and the second test electrode is electrically connected to the test circuit layer 60 through the second via hole.

In one embodiment, a first connection terminal (not shown) is formed in the first electrode, and a second connection terminal (not shown) is formed in the test circuit layer, and the first test electrode is electrically connected to the first electrode through the first connection terminal, and the second test electrode is electrically connected to the test circuit layer through the second connection terminal.

In one embodiment, a third connection terminal (not shown) is formed in the first test electrode, and a fourth connection terminal (not shown) is formed in the second test electrode, and the first test electrode is electrically connected to the first electrode through the third connection terminal, and the second test electrode is electrically connected to the test circuit layer through the fourth connection terminal.

In one embodiment, a first connection terminal (not shown) is formed in the first electrode, and a second connection terminal (not shown) is formed in the test circuit layer, and a third connection terminal (not shown) is formed in the first test electrode, and a fourth connection terminal (not shown) is formed in the second test electrode, and the first connection terminal is electrically connected to the third connection terminal, and the second connection terminal is electrically connected to the fourth connection terminal.

Referring to FIG. 3, it is a second schematic structural view of a display panel according to one embodiment of the present invention. The display panel includes a substrate 10, a first metal layer, a gate insulating layer 30, a second metal layer, an insulating layer 50, a test circuit layer 60, and an electrostatic test electrode.

The difference between FIG. 3 and FIG. 2 is that the display panel further includes a color resist layer 80 formed on a side of the insulating layer 50 away from the second metal layer, and the test circuit layer 60 is formed on a side of the color resist layer 80 away from the insulating layer 50.

In the embodiment, the display panel is a color filter on array (COA) type liquid crystal display panel, and the COA type display panel refers to a liquid crystal display panel manufactured by using COA technology. The COA technology used in the field of liquid crystal display technology includes integrating a color filter and an array substrate, that is, applying a color resist to an array substrate to form a color filter layer. Because COA technology can reduce parasitic capacitance, increase an aperture ratio, and avoid uneven brightness, it has gradually surpassed conventional non-COA technology and plays an important role in the world.

The gate insulating layer 30 is disposed between the test circuit layer 60 and the first electrode 20, and the insulating layer 50 and the color resist layer 80 are further formed on the gate insulating layer 30. In the slope region 200, a thickness of the insulating layer 30 is further increased, which is not less than a thickness of the gate insulating layer 30 disposed in the intermediate region. Therefore, the gate insulating layer 30 disposed in the slope region 200 is less likely to be broken down, and the accuracy of the electrostatic breakdown measuring is further improved.

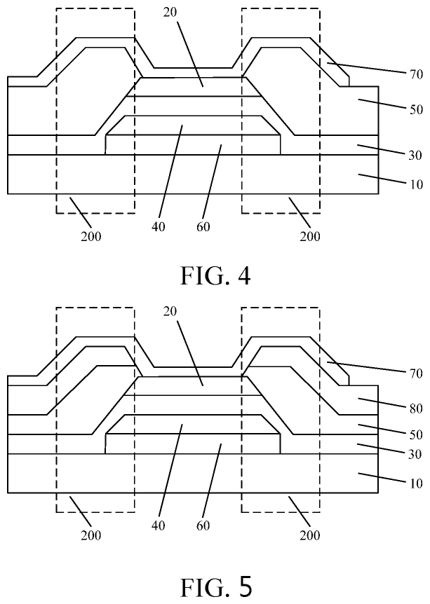

Referring to FIG. 4, it is a third schematic structural view of a display panel according to one embodiment of the present invention. The display panel includes a substrate 10, a first metal layer, a gate insulating layer 30, a second metal layer, an insulating layer 50, a test circuit layer 60, and an electrostatic test electrode.

The test circuit layer 60 is formed on the substrate 10, and the second metal layer is formed on a side of the test circuit layer 60 away from the substrate 10, and the gate insulating layer 30 is formed on a side of the second metal layer away from the test circuit layer 60, and the first metal layer is formed on a side of the gate insulating layer 30 away from the second metal layer, and the insulating layer 50 is formed on a side of the first metal layer away from the gate insulating layer 30.

The second metal layer is patterned to form a second electrode 40, and the first metal layer is patterned to form a first electrode 20, and a projection of the second electrode 40 and a projection of the first electrode 20 are overlapped on the substrate 10. The overlapping region corresponds to the gate insulating layer 30 disposed in the intermediate region which has a general thickness. Thus, when current is applied to the first electrode 20 and the second electrode 40, the gate insulating layer 30 disposed in the slope region 200 does not have current accumulation, that is, the current only acts on the gate insulating layer 30 disposed in the intermediate region, and the electrostatic breakdown resistance characteristic of the gate insulating layer can be measured more accurately.

A test circuit layer 60 electrically connected to the second electrode 40, and a connection region is disposed in a projection area of the second electrode 40 on the substrate 10.

The connection region electrically connecting the test circuit layer 60 to the second electrode 40 is disposed in a projection area of the second electrode 40 on the substrate 10, that is, the connection region is merely disposed at an intermediate region of the gate insulating layer 30, in which the intermediate region has a general thickness. When there is a current on the test circuit layer 60 and the first electrode 20, the gate insulating layer 30 disposed in the slope region 200 does not have a current accumulation, that is, current only acts on the gate insulating layer 30 disposed in the intermediate region, and electrostatic breakdown resistance characteristics of the gate insulating layer 30 can be measured more accurately.

The gate insulating layer 30 generally includes silicon oxide (SiOx), silicon nitride (SiNx), silicon oxynitride (SiON), or be a sandwich structure made of silicon oxide (SiOx), silicon nitride (SiNx), silicon oxynitride (SiON). The gate insulating layer 30 is formed on the second metal layer by a chemical vapor deposition method.

The insulating layer 50 is formed on a side of the first metal layer away from the gate insulating layer 30.

In one embodiment, the insulating layer 50 is a passivation layer, and material of the insulating layer 50 includes silicon oxide (SiOx), silicon nitride (SiNx), or be a sandwich structure made of silicon oxide (SiOx) and silicon nitride (SiNx), which is used to protect the second electrode 40, so the second electrode 40 is prevented by keeping water vapor or oxygen away. Therefore, corrosion or oxidation can be prevented.

In one embodiment, the insulating layer 50 is an interlayer insulating layer.

In one embodiment, the insulating layer 50 is a stacking structure including a passivation layer and an interlayer insulating layer. The interlayer insulating layer is formed on a side of the second metal layer away from the gate insulating layer 30. The passivation layer is formed on a side of the interlayer insulating layer away from the second metal layer. Material of the interlayer insulating layer is organic photoresist, and material of the passivation layer includes silicon oxide (SiOx), silicon nitride (SiNx), or be a sandwich structure made of silicon oxide (SiOx) and silicon nitride (SiNx).

In one embodiment, the display panel includes a conductive layer 70. At least one via hole (not shown) is formed on the insulating layer 50, and the least one via hole completely passes through the insulating layer 50, so the second electrode 40 is exposed by the at least one via hole and the conductive layer 70 is electrically connected to the second electrode 40 by the at least one via hole.

In one embodiment, the at least one via hole is formed by etching the insulating layer 50, specifically the etching may be dry etching or wet etching. Of course, the at least one via hole can also be formed by other methods. The embodiment does not limit method of forming the at least one via hole.

In one embodiment, a display panel is a liquid crystal display panel, and the conductive layer 70 is a pixel electrode of the liquid crystal display panel.

In one embodiment, a display panel is an organic light emitting diode (OLED) display panel, and the conductive layer 60 is a common electrode of the OLED display panel. The common electrode is a transparent conductive layer made of indium tin oxide (ITO).

In one embodiment, the display panel includes a low temperature polycrystalline silicon thin film transistor, and the second metal layer is further patterned to form a gate of the low temperature polycrystalline silicon thin film transistor.

Low temperature polycrystalline silicon thin film transistors have advantages of low temperature manufacturing of the thin film transistors, high carrier mobility, and small device sizes, and are widely used in display panels. In one embodiment, the low temperature polycrystalline silicon thin film transistor is a bottom gate structure, and the second metal layer is patterned to form a gate of the low temperature polycrystalline silicon thin film. The gate of the low temperature polycrystalline silicon thin film and the second electrode 40 are disposed on the same layer.

In one embodiment, the display panel includes an oxide thin film transistor, and the first metal layer is further patterned to form a gate of the oxide thin film transistor.

Oxide thin film transistors have a simple manufacturing process, few lithography process, and good uniformity, and are widely used for high-generation and large-sized display panels. In the embodiment, the oxide thin film transistor is a top gate structure, and the first metal layer is patterned to form a gate of the oxide thin film transistor. The gate of the oxide thin film transistor and the first electrode 20 are disposed on the same layer.

In one embodiment, the display panel includes a storage capacitor, and the first metal layer is a first metal plate of the storage capacitor and the second metal layer is a second metal plate of the storage capacitor.

In one embodiment, a signal is transmitted from the second electrode 40 to the test circuit layer 60. When the electrostatic test electrode is operated, the first test electrode is electrically connected to the first electrode 20 and the second test electrode is electrically connected to the test circuit layer 60. The insulating layer 50 is further formed on the gate insulating layer 30 and is also disposed between the test circuit layer 60 and the first electrode 20. A thickness of the insulating layer 50 disposed in the slope region 200 is increased, and the thickness of the insulating layer 50 disposed in the slope region 200 is not less than a thickness of the gate insulating layer 30 disposed in the intermediate region. Meanwhile, projections of the second electrode 40 and the first electrode 20 are overlapped on the substrate 10, and the test circuit layer 60 is electrically connected to the second electrode 40, and the connection region is disposed in the projection area of the second electrode 40 on the substrate 10. Thus, when current is applied to the electrostatic test electrode, the gate insulating layer 30 disposed in the slope region 200 does not have current accumulation, that is, the current only acts on the gate insulating layer 30 disposed in the intermediate region.

Therefore, when a test current applied to the electrostatic test electrode is gradually increased, the gate insulating layer 30 disposed in the slope region 200 is not first broken down. In contrast, the gate insulating layer 30 disposed in the intermediate region is first broken down, so that a current value measured by the electrostatic test electrode when the first test electrode and the second test electrode are electrically conductive, and the measured current value correctly reflects the electrostatic breakdown resistance characteristic of the gate insulating layer disposed in the intermediate region which has a general thickness.

There are several methods to make the electrostatic test electrode to connect to the display panel. In one embodiment, the first electrode 20 is formed with a first via hole (not shown), and the test circuit layer 60 is formed with a second via hole (not shown). The first test electrode is electrically connected to the first electrode 20 through the first via hole, and the second test electrode is electrically connected to the test circuit layer 60 through the second via hole.

In one embodiment, a first connection terminal (not shown) is formed in the first electrode, and a second connection terminal (not shown) is formed in the test circuit layer, and the first test electrode is electrically connected to the first electrode through the first connection terminal, and the second test electrode is electrically connected to the test circuit layer through the second connection terminal.

In one embodiment, a third connection terminal (not shown) is formed in the first test electrode, and a fourth connection terminal (not shown) is formed in the second test electrode, and the first test electrode is electrically connected to the first electrode through the third connection terminal, and the second test electrode is electrically connected to the test circuit layer through the fourth connection terminal.

In one embodiment, a first connection terminal (not shown) is formed in the first electrode, and a second connection terminal (not shown) is formed in the test circuit layer, and a third connection terminal (not shown) is formed in the first test electrode, and a fourth connection terminal (not shown) is formed in the second test electrode, and the first connection terminal is electrically connected to the third connection terminal, and the second connection terminal is electrically connected to the fourth connection terminal.

Referring to FIG. 5, it is a fourth schematic structural view of a display panel according to one embodiment of the present invention. The display panel includes a substrate 10, a first metal layer, a gate insulating layer 30, a second metal layer, an insulating layer 50, a test circuit layer 60, and an electrostatic test electrode. The difference between FIG. 5 and FIG. 4 is that the display panel further includes a color resist layer 80 formed on a side of the insulating layer 50 away from the second metal layer, and the test circuit layer 60 is formed on a side of the color resist layer 80 away from the insulating layer 50.

In the embodiment, the display panel is a color filter on array (COA) type liquid crystal display panel, and the COA type display panel refers to a liquid crystal display panel manufactured by using COA technology. The COA technology used in the field of liquid crystal display technology includes integrating a color filter and an array substrate, that is, applying a color resist to an array substrate to form a color filter layer. Because COA technology can reduce parasitic capacitance, increase the aperture ratio, and avoid uneven brightness, it has gradually surpassed conventional non-COA technology and plays an important role in the world.

The gate insulating layer 30 is disposed between the test circuit layer 60 and the first electrode 20, and the insulating layer 50 and the color resist layer 80 are further formed on the gate insulating layer 30. In the slope region 200, a thickness of the insulating layer 30 is further increased, which is not less than a thickness of the gate insulating layer 30 disposed in the intermediate region. Therefore, the gate insulating layer 30 disposed in the slope region 200 is less likely to be broken down, and the accuracy of the electrostatic breakdown measuring is further improved.

A display panel includes a substrate, a first metal layer, a second metal layer, a gate insulating layer, an insulating layer, a test circuit layer, and an electrostatic test electrode. The first metal layer is patterned to form a first electrode. The second metal layer is patterned to form a second electrode. A projection of the second electrode and a projection of the first electrode are overlapped on the substrate. The gate insulating layer is disposed between the first metal layer and the second metal layers. The test circuit layer is electrically connected to the second electrode, and a connection region is disposed in a projection area of the second electrode on the substrate. The electrostatic test electrode includes a first test electrode and a second test electrode, the first test electrode is electrically connected to the first electrode, and the second test electrode is electrically connected to the test circuit layer. A gate insulating layer is further disposed between the first metal layer and the test circuit layer, so a slope region of the gate insulating layer is thicker and is hard to generate static electricity. Therefore, the electrostatic test electrode can measure an antistatic ability of the gate insulating layer disposed in an intermediate region.

In the above, the present application has been described in the above preferred embodiments, but the preferred embodiments are not intended to limit the scope of the invention, and a person skilled in the art may make various modifications without departing from the spirit and scope of the application. The scope of the present application is determined by claims.

What is claimed is:

1. A display panel, comprising:
a substrate;
a first metal layer, wherein the first metal layer is patterned to form a first electrode;
a second metal layer, wherein the second metal layer is patterned to form a second electrode, and a projection of the second electrode and a projection of the first electrode are overlapped on the substrate;
a gate insulating layer disposed between the first metal layer and the second metal layer;
an insulating layer;
a test circuit layer electrically connected to the second electrode, wherein a connection region is disposed in a projection area of the second electrode on the substrate; and
an electrostatic test electrode, wherein the electrostatic test electrode comprises a first test electrode and a second test electrode, the first test electrode is electrically connected to the first electrode, and the second test electrode is electrically connected to the test circuit layer.

2. The display panel according to claim 1, wherein the first metal layer is formed on the substrate, and the gate insulating layer is formed on a side of the first metal layer away from the substrate, and the second metal layer is formed on a side of the gate insulating layer away from the first metal layer, and the insulating layer is formed on a side of the second metal layer away from the gate insulating layer, and the test circuit layer is formed on a side of the insulating layer away from the second metal layer.

3. The display panel according to claim 2, wherein the display panel comprises a low temperature polycrystalline silicon thin film transistor, and the first metal layer is further patterned to form a gate of the low temperature polycrystalline silicon thin film transistor.

4. The display panel according to claim 2, wherein the display panel comprises an oxide thin film transistor, and the second metal layer is further patterned to form a gate of the oxide thin film transistor.

5. The display panel according to claim 2, wherein the display panel comprises a storage capacitor, and the first metal layer is patterned to form a first metal plate of the storage capacitor, and the second metal layer is patterned to form a second metal plate of the storage capacitor.

6. The display panel according to claim 2, wherein the insulating layer is a passivation layer.

7. The display panel according to claim 2, wherein the insulating layer is a stacking structure including a passivation layer and an interlayer insulating layer.

8. The display panel according to claim 2, wherein the display panel is a liquid crystal display panel, and the test circuit layer is a pixel electrode of the liquid crystal display panel.

9. The display panel according to claim 2, wherein the display panel is an organic light emitting diode (OLED) display panel, and the test circuit layer is a common electrode of the OLED display panel.

10. The display panel according to claim 1, wherein the test circuit layer is formed on the substrate, and the second metal layer is formed on a side of the test circuit layer away from the substrate, and the gate insulating layer is formed on a side of the second metal layer away from the test circuit layer, and the first metal layer is formed on a side of the gate insulating layer away from the second metal layer, and the insulating layer is formed on a side of the first metal layer away from the gate insulating layer.

11. The display panel according to claim 10, wherein the display panel comprises a low temperature polycrystalline silicon thin film transistor, and the second metal layer is further patterned to form a gate of the low temperature polycrystalline silicon thin film transistor.

12. The display panel according to claim 10, wherein the display panel comprises an oxide thin film transistor, and the first metal layer is further patterned to form a gate of the oxide thin film transistor.

13. The display panel according to claim 10, wherein the display panel comprises a storage capacitor, and the first metal layer is patterned to form a first metal plate of the storage capacitor, and the second metal layer is patterned to form a second metal plate of the storage capacitor.

14. The display panel according to claim 10, wherein the insulating layer is a passivation layer.

15. The display panel according to claim 10, wherein the insulating layer is an interlayer insulating layer.

16. The display panel according to claim 10, wherein the insulating layer is a stacking structure including a passivation layer and an interlayer insulating layer.

17. The display panel according to claim 1, wherein a first via hole is defined in the first electrode, and a second via hole is defined in the test circuit layer, and the first test electrode is electrically connected to the first electrode through the first via hole, and the second test electrode is electrically connected to the test circuit layer through the second via hole.

18. The display panel according to claim 1, wherein a first connection terminal is formed in the first electrode, and a second connection terminal is formed in the test circuit layer, and the first test electrode is electrically connected to the first electrode through the first connection terminal, and the second test electrode is electrically connected to the test circuit layer through the second connection terminal.

19. The display panel according to claim 1, wherein a third connection terminal is formed in the first test electrode, and a fourth connection terminal is formed in the second test electrode, and the first test electrode is electrically connected to the first electrode through the third connection terminal, and the second test electrode is electrically connected to the test circuit layer through the fourth connection terminal.

20. The display panel according to claim 1, wherein a first connection terminal is formed in the first electrode, and a second connection terminal is formed in the test circuit layer, and a third connection terminal is formed in the first test electrode, and a fourth connection terminal is formed in the second test electrode, and the first connection terminal is electrically connected to the third connection terminal, and the second connection terminal is electrically connected to the fourth connection terminal.
